(19) United States
(12) Patent Application Publication
(10) Pub. No.: US 2026/0159952 A1
(43) Pub. Date: Jun. 11, 2026

(54) SEMICONDUCTOR MANUFACTURING APPARATUS

(71) Applicant: NuFlare Technology, Inc., Yokohama-shi (JP)

(72) Inventor: Toru WATANABE, Yokohama-shi (JP)

(73) Assignee: NuFlare Technology, Inc., Yokohama-shi (JP)

(21) Appl. No.: 19/332,689

(22) Filed: Sep. 18, 2025

(30) Foreign Application Priority Data
Dec. 6, 2024 (JP) 2024-213923

(51) Int. Cl. C23C 16/52; C23C 16/458

(52) U.S. Cl. CPC C23C 16/52; C23C 16/4584; C23C 16/4586

(57) ABSTRACT

According to an embodiment, semiconductor manufacturing apparatus includes a chamber, a susceptor holding a wafer, a rotating body configured to rotate the susceptor about a predetermined central axis, a first radiation thermometer configured to measure a temperature at a first temperature measurement position of the wafer, a second radiation thermometer configured to measure a temperature at a second temperature measurement position of the wafer, a first heater for heating a central region of the wafer, a second heater for heating an outer region of the wafer, and a controller that controls power applied to each of the first heater and the second heater. A second distance from the central axis to the second temperature measurement position is longer than a first distance from the central axis to the first temperature measurement position and is shorter than 0.8 times a radius of the wafer.

### CROSS-REFERENCE TO RELATED APPLICATIONS

This application is based upon and claims the benefit of priority from Japanese Patent Application No. 2024-213923, filed Dec. 6, 2024, the entire contents of which are incorporated herein by reference.

### FIELD

Embodiments described herein relate generally to a semiconductor manufacturing apparatus.

### BACKGROUND

In a semiconductor manufacturing apparatus, accurately monitoring the temperature of a semiconductor substrate (hereinafter also referred to as a “wafer”) and controlling it using a heating system, such as a heater, are essential technologies for ensuring the stable operation of the apparatus and for producing high-quality wafers. For example, in a CVD (Chemical Vapor Deposition) apparatus, which is a type of reactor equipped with a plurality of heaters, high-quality wafers can be obtained by adjusting the output balance of the individual heaters. However, in a conventional semiconductor manufacturing apparatus that measures wafer temperature and adjusts heater output to achieve a target temperature, the balance of heater output varies depending on the temperature measurement positions on the wafer, making it difficult to effectively manage the lifespans of the heaters.

For example, Patent Document 1 (Jpn. Pat. Appln. KOKAI Publication No. 2019-106462) discloses a temperature measurement method in which the reading speed is adjusted according to the rotational speed of the wafer, in order to avoid interference from an orientation flat, which is typically present on wafers of 6 inches or less, when measuring the temperature at the outer periphery of the wafer. However, Patent Document 1 does not mention the specific temperature measurement position on the outer periphery.

For example, Patent Document 2 (Jpn. Pat. Appln. KOKAI Publication 2006-303289) discloses a temperature measurement method that uses the arithmetic average of wafer temperatures based on two measurement means as a countermeasure for misalignment between a wafer and a susceptor. However, Patent Document 2 does not mention the relationship between the temperature measurement position and a heating system such as a heater.

### SUMMARY

The present invention has been made in consideration of these points. That is, an object of the present invention is to provide semiconductor manufacturing apparatus capable of controlling the temperature measurement position on the wafer and appropriately managing the power applied to the heater.

According to a first aspect of the present invention, semiconductor manufacturing apparatus includes a chamber, a susceptor provided inside the chamber and capable of holding a wafer placed on an upper face thereof, a rotating body provided inside the chamber and configured to rotate the susceptor about a predetermined central axis, a first radiation thermometer provided above the chamber and configured to measure a temperature at a first temperature measurement position of the wafer placed on the susceptor, a second radiation thermometer provided adjacent to the first radiation thermometer above the chamber and configured to measure a temperature at a second temperature measurement position of the wafer placed on the susceptor, a first heater provided below the susceptor for heating a central region of the wafer, a second heater provided below the susceptor for heating an outer region of the wafer, and a controller that controls power applied to each of the first heater and the second heater to adjust the first temperature measurement position and the second temperature measurement position of the wafer to predetermined temperatures, based on temperature measurement data from the first radiation thermometer and the second radiation thermometer. A second distance from the central axis to the second temperature measurement position is longer than a first distance from the central axis to the first temperature measurement position and is shorter than 0.8 times a radius of the wafer.

### BRIEF DESCRIPTION OF THE DRAWINGS

FIG. 1 is a cross-sectional view illustrating an example of the configuration of a semiconductor manufacturing apparatus according to a first embodiment.

FIG. 2 is a block diagram illustrating an example of the functional configuration for wafer temperature control in a control unit provided in the semiconductor manufacturing apparatus according to the first embodiment.

FIG. 3 is a plan view of a susceptor with a wafer placed thereon in the semiconductor manufacturing apparatus according to the first embodiment.

FIG. 4 is a plan view of a first heater and a second heater that are provided in the semiconductor manufacturing apparatus according to the first embodiment.

FIG. 5 is a cross-sectional view of a susceptor and a wafer and illustrates temperature measurement positions of a first radiation thermometer and a second radiation thermometer in a comparative example.

FIG. 6 is a cross-sectional view of a susceptor and a wafer and illustrates temperature measurement positions of a first radiation thermometer and a second radiation thermometer in an example of the first embodiment.

FIG. 7 is a cross-sectional view illustrating the relationship between the temperature measurement positions of the first and second radiation thermometers and the thermal radiation from the first and second heaters in a comparative example.

FIG. 8 is a diagram illustrating a wafer temperature profile and the apparent power supplied to the first and second heaters in a comparative example.

FIG. 9 is a cross-sectional view illustrating the relationship between the temperature measurement positions of the first and second radiation thermometers and the thermal radiation from the first and second heaters in the example of the first embodiment.

FIG. 10 is a diagram illustrating a wafer temperature profile and apparent power supplied to the first and second heaters in the example of the first embodiment.

FIG. 11 is a graph illustrating the relationship between the ratio of the temperature measurement position M2 to the wafer radius and the heater output balance ratio.

FIG. 12 is a cross-sectional view of a susceptor, a first heater, a second heater, and a wafer and illustrates the relationship between the temperature measurement positions of the first and second radiation thermometers and the first and second heaters in a comparative example.

FIG. 13 is a cross-sectional view of a susceptor, a first heater, a second heater, and a wafer and illustrates the relationship between the temperature measurement positions of the first and second radiation thermometers and the first and second heaters in an example of a second embodiment.

FIG. 14 is a cross-sectional view of a susceptor and a wafer and illustrates the relationship between the temperature measurement positions of the first and second radiation thermometers and the warpage of the wafer in a comparative example.

FIG. 15 is a cross-sectional view of a susceptor and a wafer and illustrates the relationship between the temperature measurement positions of the first and second radiation thermometers and the warpage of the wafer in an example of a third embodiment.

### DETAILED DESCRIPTION

A description will now be given of embodiments with reference to the accompanying drawings. The embodiments illustrate a device and a method for embodying the technical idea of the invention. The drawings are schematic or conceptual, and the dimensions and scales shown are not necessarily the same as those of the actual products. The technical concept underlying the present invention is not limited by the shapes, structures, arrangements, etc. of the components.

In the embodiments described below, reference will be made to a case where the semiconductor manufacturing apparatus is a single-wafer CVD apparatus. However, the semiconductor manufacturing apparatus is not limited to a CVD apparatus. The semiconductor manufacturing apparatus may be an annealing apparatus or an epitaxial growth apparatus. As long as the semiconductor manufacturing apparatus includes a heating mechanism for a single wafer, the present embodiment is applicable.

### 1. First Embodiment

### 1.1 Apparatus Configuration

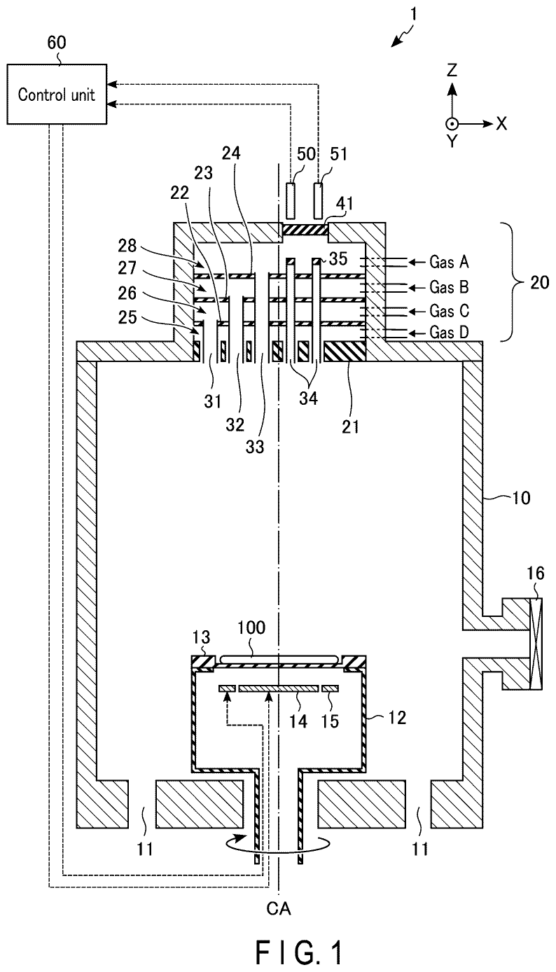

First, with reference to FIG. 1, an example of the overall configuration of the semiconductor manufacturing apparatus 1 will be described. FIG. 1 is a cross-sectional view illustrating the example of the configuration of the semiconductor manufacturing apparatus 1.

In the description below, the direction of gravity is defined as “down” and the opposite direction is defined as “up” in the state where the semiconductor manufacturing apparatus 1 is installed. In the cross-sectional view of the semiconductor manufacturing apparatus 1, the lower part of the drawing corresponds to the lower side of the semiconductor manufacturing apparatus 1, and the upper part of the drawing corresponds to the upper side of the semiconductor manufacturing apparatus 1. In the semiconductor manufacturing apparatus 1, the vertical direction is defined as the Z direction. The direction that intersects the Z direction is defined as the X direction, and the direction that intersects both the X and Z directions is defined as the Y direction. The XY plane, which is defined by the X and Y directions, is parallel to the ground surface of the semiconductor manufacturing apparatus 1.

As shown in FIG. 1, the semiconductor manufacturing apparatus 1 includes a chamber 10, an exhaust port 11, a rotating body 12, a susceptor 13, a first heater 14, a second heater 15, a gate valve 16, a gas supply unit 20, a rectifying plate 21, a first partition plate 22, a second partition plate 23, a third partition plate 24, gas supply nozzles 31, 32, and 33, a temperature measurement nozzle 34, a nozzle cap 35, a temperature measurement window 41, a first radiation thermometer 50, a second radiation thermometer 51, and a control unit 60.

The chamber 10 is a housing used for CVD. The chamber 10 is made of stainless steel, for example. Note that other materials may be used for the chamber 10. The chamber 10 is provided, for example, with a gate valve 16. A wafer 100 is transported into the chamber 10 from outside the chamber 10 via the gate valve 16. The wafer 100 may be made of Si (silicon) or another material such as SiC (silicon carbide). The chamber 10 can be maintained at an appropriate temperature by a temperature adjustment mechanism (not shown), for example, to suppress the adhesion of reaction products to the inner wall face. For example, the chamber 10 is cooled by a refrigerant (e.g., water), a cooling gas, or the like. The exhaust port 11 is located at the bottom of the chamber 10. The exhaust port 11 is coupled to an exhaust apparatus (not shown). The gas supplied into the chamber 10 is exhausted to the exhaust apparatus via the exhaust port 11. For example, the inside of the chamber 10 is maintained at a low pressure (i.e., a pressure lower than the atmospheric pressure). The pressure inside the chamber 10 may be the atmospheric pressure (normal pressure).

The rotating body 12 is provided on the bottom face of the chamber 10. The rotating body 12 can be rotated about its central axis CA, which extends in the Z direction, by a rotation mechanism (not shown). The rotating body 12 can be rotated at a high speed of 600 rpm or more, for example.

The susceptor 13 is provided on the rotating body 12. The susceptor 13 has a disk shape, for example. The center of the susceptor 13 (the central axis extending in the Z direction) coincides with the central axis CA of the rotating body 12. A recess (counterbore) for placing the wafer 100 is formed on the upper face of the susceptor 13. The wafer 100 is placed on the recess of the susceptor 13. It is preferable that the wafer 100 be placed so that its center on the XY plane coincides with the central axis CA. The semiconductor manufacturing apparatus 1 rotates the wafer 100 by rotating the rotating body 12. The susceptor 13 is made of carbon, for example. The susceptor 13 may be made of a material with heat resistance of 1700° C. or higher, such as SiC (silicon carbide), TaC (tantalum carbide), W (tungsten), or Mo (molybdenum).

The first heater 14 and the second heater 15 are located inside the rotating body 12. The first heater 14 has a disk shape centered on the central axis CA. The second heater 15 has an annular shape centered on the central axis CA. On the same XY plane, the second heater 15 is arranged so as to surround the outer periphery of the first heater 14. The configuration of the heater that heats the wafer 100 (susceptor 13) is not limited to this. The heater may be composed of three or more blocks. The heater may be a resistance heater, a lamp heater, or an induction heater. The first heater 14 and the second heater 15 heat the susceptor 13 (and the wafer 100) from the back face (lower face) of the susceptor 13. For example, in a case where the semiconductor manufacturing apparatus 1 is an SiC epitaxial growth apparatus, the wafer 100 is heated to 1500° C. or higher. The first heater 14 mainly heats the central region of the susceptor 13 (wafer 100). The second heater 15 mainly heats the peripheral region of the susceptor 13 (wafer 100). The temperatures of the first heater 14 and the second heater 15 are individually controlled by the control unit 60.

The gas supply unit 20 is installed, for example, in the upper portion of the chamber 10. The gas supply unit 20 has a cylindrical shape, for example. The inner diameter of the gas supply unit 20 is, for example, larger than the diameter of the wafer 100 and smaller than the inner diameter of the chamber 10. The gas supply unit 20 supplies various gases into the chamber 10. In the example shown in FIG. 1, gases A, B, C, and D are supplied to the gas supply unit 20. The type and number of gases supplied to the gas supply unit 20 depend on the film deposition process. Gases A, B, C, and D supplied from the gas supply unit 20 into the chamber 10 flow toward the wafer 100. The gas supply unit 20 can be maintained at an appropriate temperature by a temperature control mechanism (not shown) in order to suppress an increase in the temperatures of the supplied gases and the adhesion of reaction products to the gas supply unit 20. The gas supply unit 20 is cooled, for example, by a refrigerant (e.g., water), a cooling gas, or the like.

The rectifying plate 21 rectifies the fluid (gas) supplied from the gas supply unit 20 into the chamber 10. The rectifying plate 21 is located at the bottom of the gas supply unit 20. The rectifying plate 21 is made of quartz, for example. Note that other materials such as stainless steel may also be used for the rectifying plate 21. The rectifying plate 21 has a disk shape, for example. The diameter of the rectifying plate 21 is, for example, larger than the diameter of the wafer 100. The lower face of the rectifying plate 21 faces the upper face of the wafer 100 (susceptor 13). It is preferable that the rectifying plate 21 be positioned so that its lower face is parallel to the wafer 100 placed on the susceptor 13. The rectifying plate 21 has a plurality of through holes extending in the Z direction to supply gases into the chamber 10.

The first partition plate 22 is located between the rectifying plate 21 and the top plate of the gas supply unit 20 and spaced apart from them in the Z direction. The first partition plate 22 has a plurality of through holes through which the gas supply nozzles 31, 32, and 33 and the temperature measurement nozzle 34 pass. A first gas region 25 is provided between the rectifying plate 21 and the first partition plate 22. Gas D is supplied to the first gas region 25. Gas D is a purge gas, for example.

The second partition plate 23 is located between the first partition plate 22 and the top plate of the gas supply unit 20 and is spaced apart from them in the Z direction. The second partition plate 23 has a plurality of through holes through which the gas supply nozzles 32 and 33 and the temperature measurement nozzle 34 pass. A second gas region 26 is provided between the first partition plate 22 and the second partition plate 23. Gas C is supplied to the second gas region 26. Gas C is a CVD process gas, for example.

The third partition plate 24 is located between the second partition plate 23 and the top plate of the gas supply unit 20 and is spaced apart from them in the Z direction. The third partition plate 24 has a plurality of through holes through which the gas supply nozzle 33 and the temperature measurement nozzle 34 pass. A third gas region 27 is provided between the second partition plate 23 and the third partition plate 24. Gas B is supplied to the third gas region 27. Gas B is a CVD process gas, for example. Further, a fourth gas region 28 is provided between the third partition plate 24 and the top plate of the gas supply unit 20. Gas A is supplied to the fourth gas region 28. Gas A is a purge gas, for example. The number of partition plates provided in the gas supply unit 20 can be appropriately determined based on the types of gases to be supplied.

The gas supply nozzle 31 extends in the Z direction. The gas supply nozzle 31 penetrates the rectifying plate 21 and the first partition plate 22. Gas C in the second gas region 26 is supplied into the chamber 10 via the gas supply nozzle 31.

The gas supply nozzle 32 extends in the Z direction. The gas supply nozzle 32 penetrates the rectifying plate 21, the first partition plate 22, and the second partition plate 23. Gas B in the third gas region 27 is supplied into the chamber 10 via the gas supply nozzle 32.

The gas supply nozzle 33 extends in the Z direction. The gas supply nozzle 33 penetrates the rectifying plate 21, the first partition plate 22, the second partition plate 23, and the third partition plate 24. Gas A in the fourth gas region 28 is supplied into the chamber 10 via the gas supply nozzle 33.

Gaps are provided between the through holes of the rectifying plate 21 and the gas supply nozzles 31, 32, and 33 as well as the temperature measurement nozzle 34. Gas D in the first gas region 25 is supplied into the chamber 10 through the gap between each nozzle and the rectifying plate 21.

The temperature measurement nozzle 34 is used for measuring the temperatures of the wafer 100 by the first radiation thermometer 50 and the second radiation thermometer 51. The temperature measurement nozzle 34 extends in the Z direction. The temperature measurement nozzle 34 penetrates the rectifying plate 21, the first partition plate 22, the second partition plate 23, and the third partition plate 24. In the example shown in FIG. 1, two temperature measurement nozzles 34 corresponding to the first radiation thermometer 50 and the second radiation thermometer 51 are provided. The number of temperature measurement nozzles 34 is not limited to two. For example, one temperature measurement nozzle 34 corresponding to both the first radiation thermometer 50 and the second radiation thermometer 51 may be provided; alternatively, three or more temperature measurement nozzles 34 may be provided to allow the temperature measurement positions to be changed.

The nozzle cap 35 is located at the upper end of each of the temperature measurement nozzles 34. The nozzle cap 35 is made of quartz, for example. The nozzle cap 35 may be made of a material that can transmit the wavelength range of light measured by the first radiation thermometer 50 and the second radiation thermometer 51. The nozzle cap 35 may be omitted. In this case, gas A in the fourth gas region 28 may be supplied into the chamber 10 via the gas supply nozzle 33 and the temperature measurement nozzle 34.

The temperature measurement window 41 is located in part of the top plate (upper face) of the gas supply unit 20. The number and shapes of temperature measurement windows 41 are arbitrary. The temperature measurement window 41 passes reflected light and thermal radiation (infrared radiation) from the wafer 100. The temperature measurement window 41 is used for measuring the temperatures of the wafer 100 by the first radiation thermometer 50 and the second radiation thermometer 51. The temperature measurement window 41 is made of quartz, for example. The temperature measurement window 41 may be made of any material as long as it can transmit the wavelength range of light measured by the first radiation thermometer 50 and the second radiation thermometer 51.

The first radiation thermometer 50 and the second radiation thermometer 51 are pyrometers. The first radiation thermometer 50 and the second radiation thermometer 51 are located above the temperature measurement window 41. The first radiation thermometer 50 and the second radiation thermometer 51 measure the temperatures of the wafer 100 through the temperature measurement window 41, the nozzle cap 35, and the temperature measurement nozzle 34. The first radiation thermometer 50 and the second radiation thermometer 51 measure the temperatures of the wafer 100 in a non-contact manner, based on thermal radiation (infrared radiation) emitted from the surface of the wafer 100. The measurement principle is based on Planck's law. The first radiation thermometer 50 and the second radiation thermometer 51 are arranged, for example, side by side in the radial direction of the wafer 100. The first radiation thermometer 50 is positioned closer to the center of the wafer 100 (central axis CA) than the second radiation thermometer 51. The first radiation thermometer 50 is used to measure the temperature of the inner region of the wafer 100. The second radiation thermometer 51 is used to measure the temperature of the outer region of the wafer 100. In other words, the position at which the temperature of the wafer 100 is measured by the first radiation thermometer 50 is closer to the center of the wafer 100 (central axis CA) than the position at which the temperature of the wafer 100 is measured by the second radiation thermometer 51. One radiation thermometer may be moved in the radial direction of the wafer 100 to measure the temperatures of the inner region and the outer region of the wafer 100.

The control unit 60 controls the entire semiconductor manufacturing apparatus 1. For example, the control unit 60 includes a CPU (Central Processing Unit) that controls the semiconductor manufacturing apparatus 1, and a storage unit that stores various programs and process recipes. The control unit 60 executes a film deposition process, based on the process recipes. More specifically, the control unit 60 controls the rotation mechanism of the rotating body 12. The control unit 60 controls the first heater 14 and the second heater 15, based on the temperature measurement results obtained by the first radiation thermometer 50 and the second radiation thermometer 51. The control unit 60 controls the supply of gases to the chamber 10. The control unit 60 controls the exhaust apparatus (not shown) in order to regulate the pressure in the chamber 10. The control unit 60 controls the gate valve 16, a transport mechanism (not shown) for the wafer 100, and other components. Thus, the control unit 60 controls the loading of the wafer 100 into the chamber 10 and its unloading from the chamber 10.

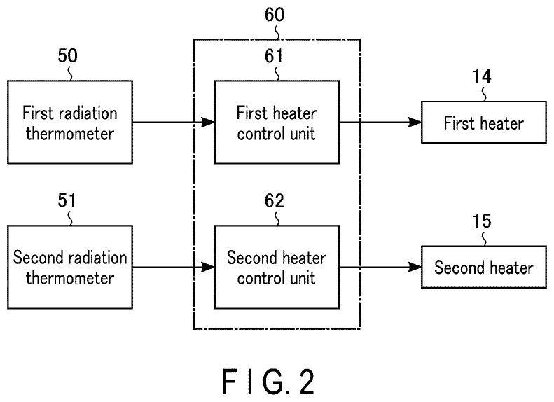

An example of a functional configuration of the control unit 60 for controlling the temperature of the wafer 100 will be described with reference to FIG. 2. FIG. 2 is a block diagram illustrating an example of the functional configuration of the control unit 60 for controlling the temperature of the wafer 100.

As shown in FIG. 2, the control unit 60 includes a first heater control unit 61 and a second heater control unit 62. The functions of the first heater control unit 61 and the second heater control unit 62 are realized, for example, by firmware or a program executed by the control unit 60.

The first heater control unit 61 controls the power applied to the first heater 14, based on the temperature measurement result of the first radiation thermometer 50 (the temperature control based on the temperature measurement result will be hereinafter referred to as “temperature adjustment control”). The first heater control unit 61 also controls the temperature of the first heater 14, based on a preset heater output (e.g., apparent power) (the temperature control based on the preset heater output will be hereinafter referred to as “fixed output control”).

Like the first heater control unit 61, the second heater control unit 62 executes temperature adjustment control of the second heater 15, based on the temperature measurement result of the second radiation thermometer 51. In addition, the second heater control unit 62 executes fixed output control of the second heater 15.

### 1.2 Planar Configuration of Susceptor

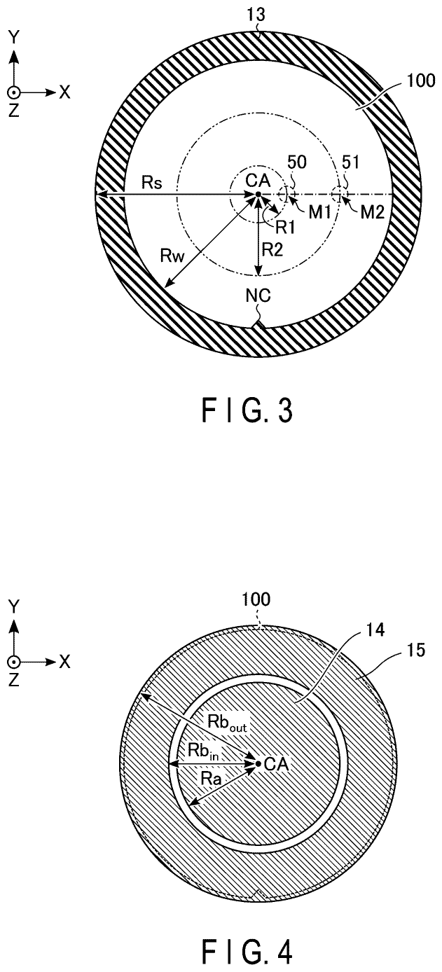

Next, an example of the planar configuration of the susceptor 13 will be described with reference to FIG. 3. FIG. 3 is a plan view of the susceptor 13, with a wafer 100 placed thereon.

As shown in FIG. 3, the wafer 100 is placed on the susceptor 13. The size of the wafer 100 is 8 inches, for example. A notch NC is formed in the wafer 100. Such notches are typically provided in silicon wafers with diameters of 8 inches or larger. Note that the size of the wafer 100 is not limited to 8 inches. The size of the wafer 100 may be 6 inches or smaller, or 12 inches or larger. In the case where the size of the wafer 100 is 6 inches or smaller, the wafer 100 is provided with an orientation flat, for example.

A recess (counterbore) for placing the wafer 100 is formed on the upper face of the susceptor 13. Thus, the wafer 100 is placed on the susceptor 13 so that its center in the XY plane coincides with the central axis CA. The susceptor 13 may be provided with recesses corresponding to a plurality of wafer sizes.

The radius Rs of the susceptor 13 is larger than the radius Rw of the wafer 100. In other words, the radius Rs of the susceptor 13 and the radius Rw of the wafer 100 satisfy the relationship Rs>Rw.

The first radiation thermometer 50 and the second radiation thermometer 51 are located above the wafer 100 (temperature measurement window 41). The wafer 100 is rotated by the rotating body 12. Therefore, the first radiation thermometer 50 and the second radiation thermometer 51 measure the temperatures on circumferences with different radii centered on the central axis CA. The rotation period of the wafer 100 and the measurement timing of the first radiation thermometer 50 and the second radiation thermometer 51 may or may not be synchronized.

For example, it is assumed that the temperature measurement position of the first radiation thermometer 50 is M1. The temperature measurement position M1 is located on a circumference of a radius R1 centered on the central axis CA. Similarly, it is assumed that the temperature measurement position of the second radiation thermometer 51 is M2. The temperature measurement position M2 is located on a circumference of a radius R2 centered on the central axis CA. In other words, the distance from the central axis CA (the center of the wafer 100) to the temperature measurement position M1 is R1, and the distance from the central axis CA (the center of the wafer 100) to the temperature measurement position M2 is R2. In this case, the radius R1 of the temperature measurement position M1, the radius R2 of the temperature measurement position M2, and the radius Rw of the wafer 100 satisfy the relationship 0≤R1<R2<Rw. In the present embodiment, in order to suppress the difference in heater output (apparent power) between the first heater 14 and the second heater 15 during temperature adjustment control, the radius R2 of the temperature measurement position M2 is set to be greater than the radius R1 of the temperature measurement position M1 and shorter than 0.8 times the radius Rw of the wafer 100 (0.8 Rw). In this case, the radius R1 of the circumference of the temperature measurement position M1, the radius R2 of the circumference of the temperature measurement position M2, and the radius Rw of the wafer 100 satisfy the relationship 0≤R1<R2<0.8 Rw. In other words, the distance R2 from the central axis CA (the center of the wafer 100) to the temperature measurement position M2 is longer than the distance R1 from the central axis CA (the center of the wafer 100) to the temperature measurement position M1 and is shorter than 0.8 times the radius Rw of the wafer 100.

### 1.3 Planar Configuration of First Heater and Second Heater

Next, an example of the planar configuration of the first heater 14 and the second heater 15 will be described with reference to FIG. 4. FIG. 4 is a plan view of the first heater 14 and the second heater 15.

As shown in FIG. 4, the first heater 14 and the second heater 15 are arranged concentrically around the central axis CA. The second heater 15 surrounds the outer circumference of the first heater 14. Assume that the radius of the disk-shaped first heater 14 is Ra. Also assume that the inner diameter of the annular second heater 15 is Rbᵢₙ, and the outer diameter thereof is Rbₒᵤₜ. The radius Ra of the first heater 14 and the inner diameter Rbᵢₙ and outer diameter Rbₒᵤₜ of the second heater 15 satisfy the relationship Ra<Rbᵢₙ<Rbₒᵤₜ. The radius Ra of the first heater 14 and the inner radius Rbᵢₙ of the second heater 15 are smaller than the radius Rw of the wafer 100. The outer diameter Rbₒᵤₜ of the second heater 15 may be smaller or larger than the radius Rw of the wafer 100. FIG. 4 shows the case where the outer diameter Rbₒᵤₜ of the second heater 15 is larger than the radius Rw of the wafer 100.

### 1.4 Specific Example of Relationship Between Temperature Measurement Positions of First and Second Radiation Thermometers and Temperature Profile of Wafer

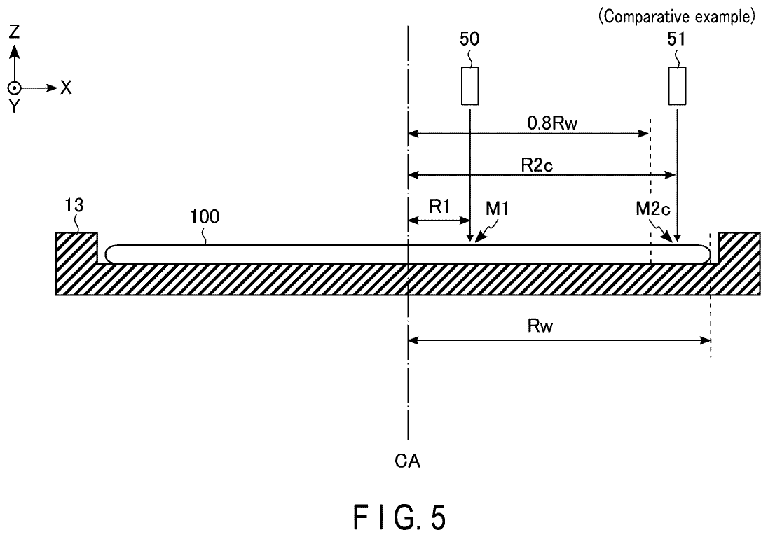

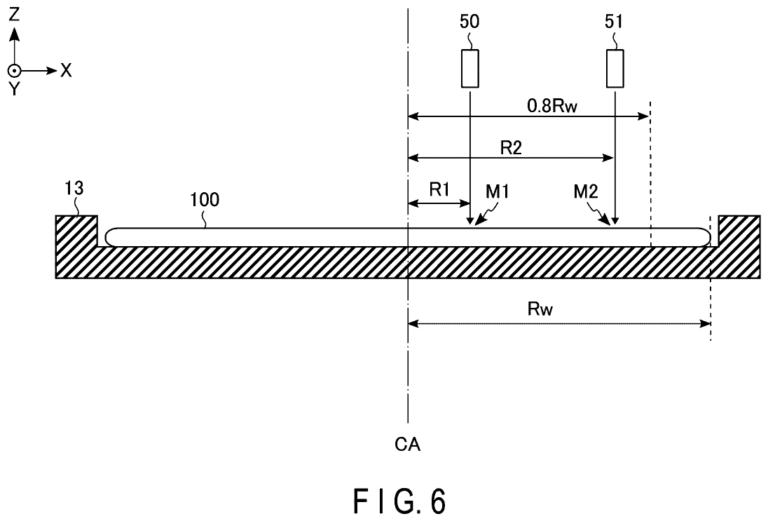

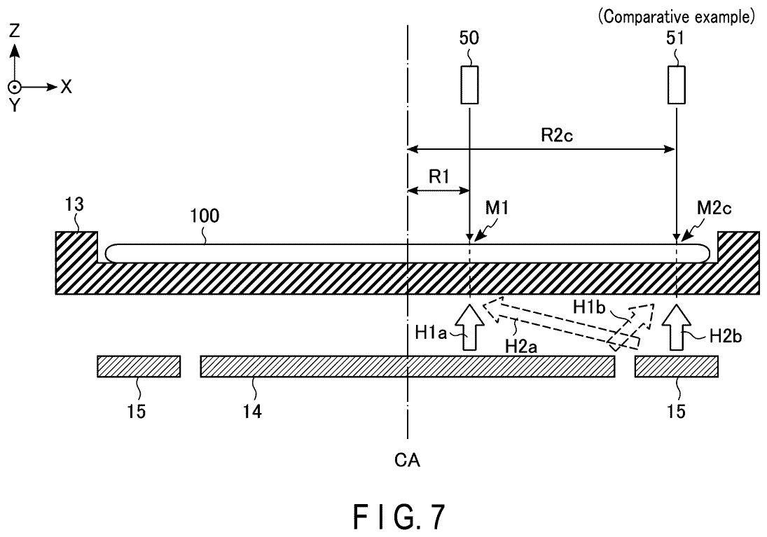

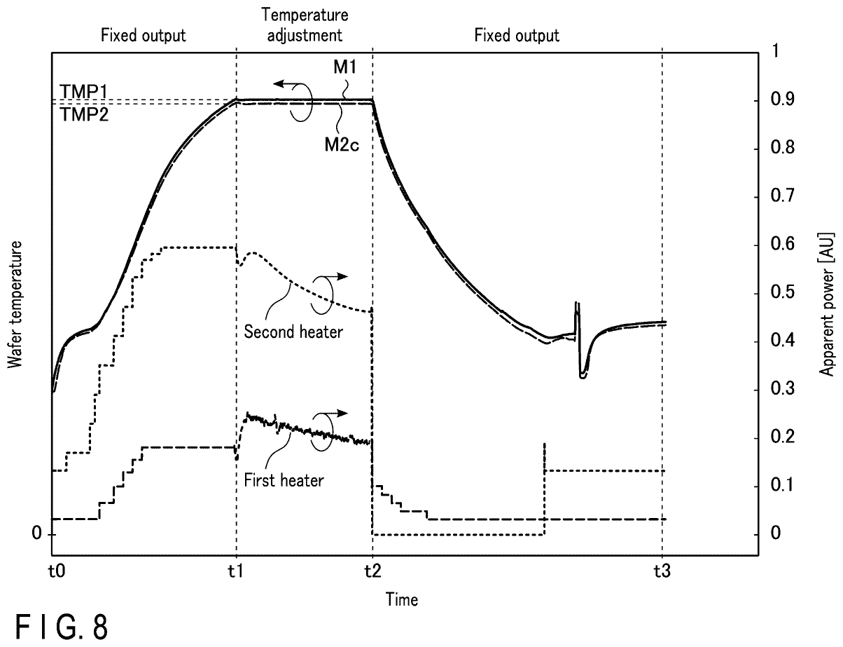

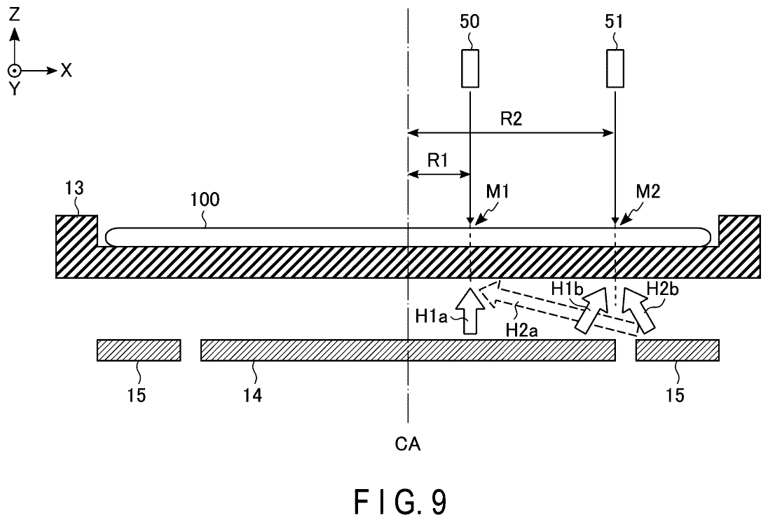

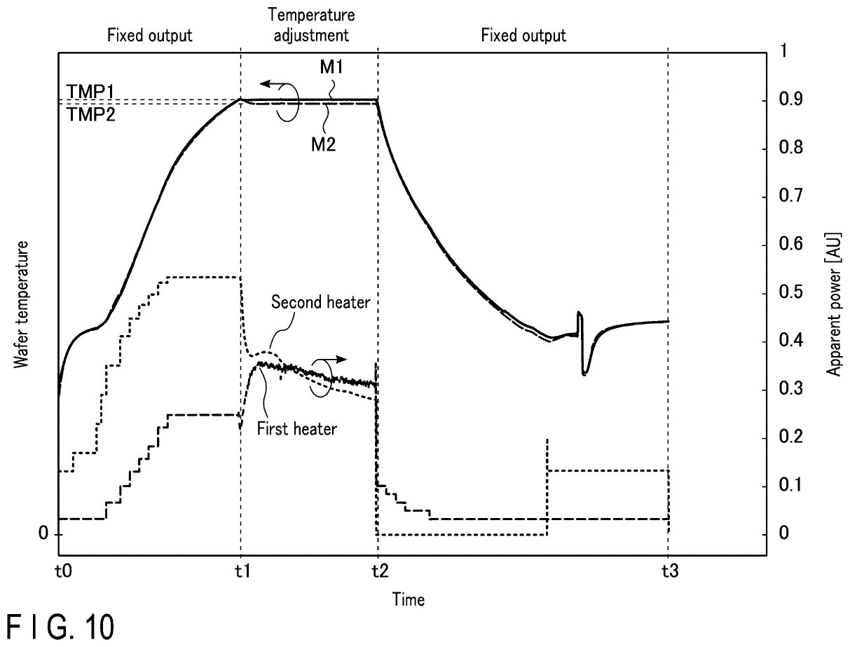

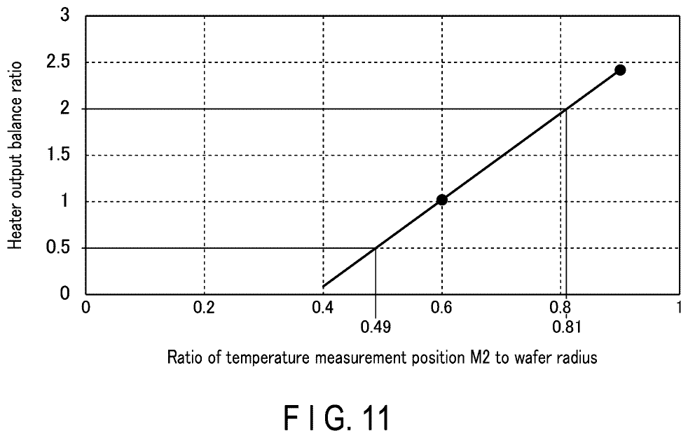

Next, a specific example of the relationship between the temperature measurement positions of the first and second radiation thermometers 50 and 51 and the temperature profile of the wafer 100 will be described with reference to FIGS. 5 to 11. FIG. 5 is a cross-sectional view of the susceptor 13 and the wafer 100 and illustrates the temperature measurement positions of the first and second radiation thermometers 50 and 51 in a comparative example. FIG. 6 is a cross-sectional view of the susceptor 13 and the wafer 100 and illustrates the temperature measurement positions of the first and second radiation thermometers 50 and 51 in an example of the present embodiment. FIG. 7 is a cross-sectional view illustrating the relationship between the temperature measurement positions M1 and M2c of the first and second radiation thermometers 50 and 51 and the thermal radiation from the first and second heaters 14 and 15 in the comparative example. FIG. 8 is a diagram illustrating the temperature profile of the wafer 100 and the apparent power supplied to the first and second heaters 14 and 15 in the comparative example. The unit of apparent power is expressed in arbitrary units (AU). FIG. 9 is a cross-sectional view illustrating the relationship between the temperature measurement positions M1 and M2 of the first and second radiation thermometers 50 and 51 and the thermal radiation from the first and second heaters 14 and 15 in the example of the present embodiment. FIG. 10 is a diagram illustrating the temperature profile of the wafer 100 and the apparent power supplied to the first heater 14 and the second heater 15 in the example of the present embodiment. The unit of apparent power is expressed in arbitrary units (AU). FIG. 11 is a graph illustrating the relationship between the ratio of the temperature measurement position M2 to the wafer radius Rw and the heater output balance ratio. In the description below, the focus will be placed on the temperature measurement position M2 of the second radiation thermometer 51.

First, the positional relationship between the temperature measurement positions of the first and second radiation thermometers 50 and 51 and the wafer 100 will be described for both the comparative example and the example of the present embodiment.

As shown in FIGS. 5 and 6, the temperature measurement position M1 of the first radiation thermometer 50 in the comparative example is the same as the temperature measurement position M1 in the embodiment. The temperature measurement positions M1 in both the comparative example and the example are located on a circumference with a radius R1 centered on the central axis CA. In other words, the distance from the central axis CA (the center of the wafer 100) to the temperature measurement position M1 is R1 in both the comparative example and the example. For example, the radius R1 of the temperature measurement position M1 is 0.2 times the radius Rw of the wafer 100 (R1=0.2 Rw). Note that the radius R1 of the temperature measurement position M1 is not limited to R1=0.2 Rw.

Assume that the temperature measurement position of the second radiation thermometer 51 in the comparative example is M2c, as shown in FIG. 5. The temperature measurement position M2c is located on a circumference of a radius R2c centered on the central axis CA. In other words, the distance from the central axis CA (the center of the wafer 100) to the temperature measurement position M2c is R2c in the comparative example. The temperature measurement position M2c is provided at a position where 0.8 Rw<R2c<Rw. In other words, the temperature measurement position M2c is provided near the outer circumference of the wafer 100.

In contrast, the temperature measurement position M2 of the second radiation thermometer 51 in the example is located on a circumference of a radius R2 centered on the central axis CA, as shown in FIG. 6. In other words, the distance from the central axis CA (the center of the wafer 100) to the temperature measurement position M2 is R2 in the example. The temperature measurement position M2 is provided at a position where R1<R2<0.8 Rw.

Next, the relationship between the temperature measurement positions M1 and M2c and the thermal radiation from the first and second heaters 14 and 15 in the comparative example will be described.

As shown in FIG. 7, the first heater 14 is arranged below the temperature measurement position M1 of the wafer 100, with the susceptor 13 interposed. The second heater 15 is located away from the temperature measurement position M1 in a plan view seen from the Z direction. For this reason, at the temperature measurement position M1, the wafer 100 (susceptor 13) is mainly heated by the thermal radiation H1a from the first heater 14. Thus, the influence of the thermal radiation H2a from the second heater 15 on the temperature measurement position M1 is smaller than that of the thermal radiation H1a from the first heater 14.

The second heater 15 is arranged below the temperature measurement position M2c of the wafer 100, with the susceptor 13 interposed. The first heater 14 is located away from the temperature measurement position M2c in a plan view seen from the Z direction. For this reason, at the temperature measurement position M2c, the wafer 100 (susceptor 13) is mainly heated by the thermal radiation H2b from the second heater 15. Thus, the influence of the thermal radiation H1b from the first heater 14 on the temperature measurement position M2c is smaller than that of the thermal radiation H2b from the second heater 15.

Next, the temperature profile of the wafer 100 and the apparent power supplied to the first heater 14 and the second heater 15 in the comparative example will be described. The example shown in FIG. 8 illustrates a case where the wafer 100 is heated to a temperature TMP1 at the temperature measurement position M1, and to a temperature TMP2 at the position M2. In the example shown in FIG. 8, the temperature TMP2 is set to a temperature slightly lower than the temperature TMP1. Note that the temperatures TMP1 and TMP2 may be the same temperature, or the temperature TMP2 may be higher than the temperature TMP1.

As shown in FIG. 8, for example, during the temperature rise period of the wafer 100 (the period from time t0 to t1) and the temperature fall period of the wafer 100 (the period from time t2 to t3), there is a large deviation between the set temperature and the measured temperature. Thus, the control unit 60 performs fixed output control for the first heater 14 and the second heater 15 to prevent excessive apparent power from being supplied to the first heater 14 and the second heater 15. In addition, instead of the fixed output control, the control unit 60 may perform temperature adjustment control for the first heater 14 and the second heater 15, based on a preset temperature rise rate, or the like.

In the example shown in FIG. 8, during the period from time t0 to t1, the control unit 60 performs fixed output control to supply apparent power to the first heater 14 and the second heater 15 while gradually increasing the apparent power. This causes the temperature of the wafer 100 to rise gradually. For example, the control unit 60 supplies the second heater 15 with an apparent power that is at least three times that of the first heater 14. In the description below, the ratio of the apparent power supplied to the second heater 15 to the apparent power supplied to the first heater 14 will be defined as a heater output balance ratio. The heater output balance ratio during the period from time t0 to t1 is approximately 3.

During the period from time t1 to t2, the control unit 60 (first heater control unit 61) maintains the temperature of the wafer 100 at the temperature measurement position M1 at the temperature TMP1, based on the temperature measurement result of the first radiation thermometer 50. Similarly, the control unit 60 (the second heater control unit 62) maintains the temperature of the wafer 100 at the temperature measurement position M2c at the temperature TMP2, based on the temperature measurement result of the second radiation thermometer 51. That is, the temperatures of the first heater 14 and the second heater 15 are controlled by the temperature adjustment control. At this time, for example, the control unit 60 supplies the second heater 15 with an apparent power that is approximately 2.4 times that of the first heater 14. That is, the heater output balance ratio is approximately 2.4.

During the period from time t2 to time t3, the temperature of the wafer 100 is lowered. The control unit 60 performs fixed output control for the first heater 14 and the second heater 15.

Next, the relationship between the temperature measurement positions M1 and M2 and the thermal radiation from the first heater 14 and the second heater 15 in the example will be described.

As shown in FIG. 9, similarly to the description of the comparative example using FIG. 7, the first heater 14 is arranged below the temperature measurement position M1 of the wafer 100, with the susceptor 13 interposed. The second heater 15 is located away from the temperature measurement position M1 in a plan view seen from the Z direction. For this reason, at the temperature measurement position M1, the wafer 100 (susceptor 13) is mainly heated by the thermal radiation H1a from the first heater 14. Thus, the influence of the thermal radiation H2a from the second heater 15 on the temperature measurement position M1 is smaller than that of the thermal radiation H1a from the first heater 14.

In the example, the temperature measurement position M2 is provided more inward on the wafer 100 than the temperature measurement position M2c of the comparative example. Therefore, the distance from the end of the first heater 14 to the temperature measurement position M2 is shorter than the distance from the end of the first heater 14 to the temperature measurement position M2c. In the example shown in FIG. 9, the first heater 14 and the second heater 15 are arranged below and near the temperature measurement position M2 of the wafer 100, with the susceptor 13 interposed. Therefore, at the temperature measurement position M2, the wafer 100 (susceptor 13) is heated by the thermal radiation H1b from the first heater 14 and the thermal radiation H2b from the second heater 15. The influence of the thermal radiation H1b from the first heater 14 on the temperature measurement position M2 is greater than that of the thermal radiation H1b from the first heater 14 on the temperature measurement position M2c of the comparative example. Furthermore, the influence of the thermal radiation H2b from the second heater 15 on the temperature measurement position M2 is smaller than that of the thermal radiation H2b from the second heater 15 on the temperature measurement position M2c of the comparative example.

For example, in the case where the temperature measurement position M2 in the example and the temperature measurement position M2c in the comparative example (as described with reference to FIG. 7) are controlled to the same temperature, the temperature measurement position M2 is more strongly influenced by the thermal radiation H1b from the first heater 14 than the temperature measurement position M2c. Therefore, the temperature of the second heater 15 for heating the temperature measurement position M2 is lower in the example than in the comparative example. That is, the apparent power supplied to the second heater 15 is lower in the example than in the comparative example. If the apparent power supplied to the second heater 15 is reduced, the influence of the thermal radiation H2a from the second heater 15 on the temperature measurement position M1 becomes smaller compared to the comparative example. Therefore, the temperature of the first heater 14 for heating the temperature measurement position M1 is higher in the example than in the comparative example. That is, the apparent power supplied to the first heater 14 is higher in the example than in the comparative example. Therefore, if the temperature measurement position is moved from M2c to M2, the apparent power supplied to the first heater 14 tends to increase and the apparent power supplied to the second heater 15 tends to decrease.

Next, a description will be given of the temperature profile of the wafer 100 and the apparent power supplied to the first heater 14 and the second heater 15 in the example. Similar to the comparative example described with reference to FIG. 8, the example shown in FIG. 10 illustrates a case where the wafer 100 is heated to a temperature TMP1 at the temperature measurement position M1 and to a temperature TMP2 at the temperature measurement position M2.

As shown in FIG. 10, the temperature of the wafer 100 is increased during the period from time t0 to t1. In the case of the example, the apparent power supplied to the first heater 14 increases, while that supplied to the second heater 15 decreases, compared to the comparative example. By performing fixed output control, the control unit 60 supplies the second heater 15 with an apparent power that is approximately 2.1 times that of the first heater 14. That is, the heater output balance ratio is approximately 2.1. In the case of the example, the heater output balance ratio decreases compared to the comparative example.

During the period from time t1 to t2, the control unit 60 (first heater control unit 61) maintains the temperature of the wafer 100 at the temperature measurement position M1 at temperature TMP1, based on the temperature measurement result of the first radiation thermometer 50. Similarly, the control unit 60 (the second heater control unit 62) maintains the temperature of the wafer 100 at the temperature measurement position M2 at temperature TMP2, based on the temperature measurement result of the second radiation thermometer 51. That is, the temperatures of the first heater 14 and the second heater 15 are controlled by the temperature adjustment control. In the case of the example, the control unit 60 supplies approximately the same apparent power to the first heater 14 and the second heater 15. That is, the heater output balance ratio is approximately 1. In this case, the total apparent power supplied to the first heater 14 and the second heater 15 decreases compared to the comparative example described with reference to FIG. 8.

During the period from time t2 to t3, the temperature of the wafer 100 is lowered. The control unit 60 performs fixed output control for the first heater 14 and the second heater 15.

Next, the relationship between the ratio of the temperature measurement position M2 to the wafer radius Rw and the heater output balance ratio will be described.

As shown in FIG. 11, the heater output balance ratio tends to increase as the ratio of the temperature measurement position M2 to the wafer radius Rw increases. In other words, the closer the radius R2 of the temperature measurement point M2 is to the radius Rw of the wafer 100, the greater the apparent power supplied to the second heater 15 becomes relative to that supplied to the first heater 14.

To suppress deformation caused by temperature variations in the face of the wafer 100 and to appropriately manage the lifespans of the first heater 14 and the second heater 15, it is preferable to set the upper limit of the heater output balance ratio to less than 2. As shown in FIG. 11, in the case where the heater output balance ratio is 2, the ratio of the temperature measurement position M2 to the wafer radius Rw is 0.81. Thus, it is preferable to set the temperature measurement position M2 to less than 0.8 Rw (0.8 times the radius Rw). Therefore, the radius R2 of the temperature measurement position M2 is set to satisfy R1<R2<0.8 Rw. Similarly, it is even more preferable to set the lower limit of the heater output balance ratio to greater than 0.5. As shown in FIG. 11, in the case where the heater output balance ratio is 0.5, the ratio of the temperature measurement position M2 to the wafer radius Rw is 0.49. Thus, it is preferable to set the temperature measurement position M2 to greater than 0.5 Rw (0.5 times the radius Rw). Therefore, in the case where the radius R1 of the temperature measurement position M1 is smaller than 0.5 Rw (R1<0.5 Rw), the radius R2 of the temperature measurement position M2 is set to satisfy 0.5 Rw<R2<0.8 Rw.

### 1.5 Advantages of Present Embodiment

For example, if the heater output balance ratio exceeds 2, the heating balance in the face of the wafer 100 deteriorates, and the temperature variation in the face increases. If the temperature variation increases, the wafer 100 becomes more likely to deform, warp, or have crystal defects. In addition, since the second heater 15 is supplied with a larger apparent power than that of the first heater 14, the load on the second heater 15 increases. As a result, the lifespan of the second heater 15 becomes shorter than that of the first heater 14. If the difference in lifespan between the first heater 14 and the second heater 15 increases, maintenance (i.e., part replacement) must be performed for each heater at different times. Thus, the operating time of the semiconductor manufacturing apparatus 1 becomes shorter and the processing capacity decreases. In addition, if the lifespans shorten and the maintenance frequency increases, the maintenance cost increases.

In contrast, with the configuration according to the present embodiment, the temperature measurement position M2 of the second radiation thermometer 51 can be set to satisfy R1<R2<0.8 Rw. That is, the radius R2 of the temperature measurement position M2 can be made larger than the radius R1 of the temperature measurement position M1 and smaller than 0.8 times the radius Rw of the wafer 100 (0.8 Rw). Thus, the heater output balance ratio can be kept at a value less than 2. This allows the heater lifespans to be appropriately managed.

Furthermore, with the configuration according to the present embodiment, the radius R2 of the temperature measurement position M2 can be set to satisfy 0.5 Rw<R2<0.8 Rw in the case where the radius R1 of the temperature measurement position M1 of the first radiation thermometer 50 is smaller than 0.5 Rw (R1<0.5 Rw). That is, the radius R2 of the temperature measurement position M2 can be made larger than 0.5 times the radius Rw of the wafer 100 (0.5 Rw) and smaller than 0.8 times the radius Rw of the wafer 100 (0.8 Rw). Thus, the heater output balance ratio can be controlled to be larger than 0.5 and smaller than 2. This allows the heater lifespans to be appropriately managed.

### 2. Second Embodiment

Next, the second embodiment will be described. In connection with the second embodiment, a description will be given of a case where the setting range of the temperature measurement position M2 is determined based on the positional relationship between the first heater 14 and the second heater 15. In the description below, the focus will be placed on differences from the first embodiment.

### 2.1 Relationship Between Temperature Measurement Positions of First and Second Radiation Thermometers and First and Second Heaters

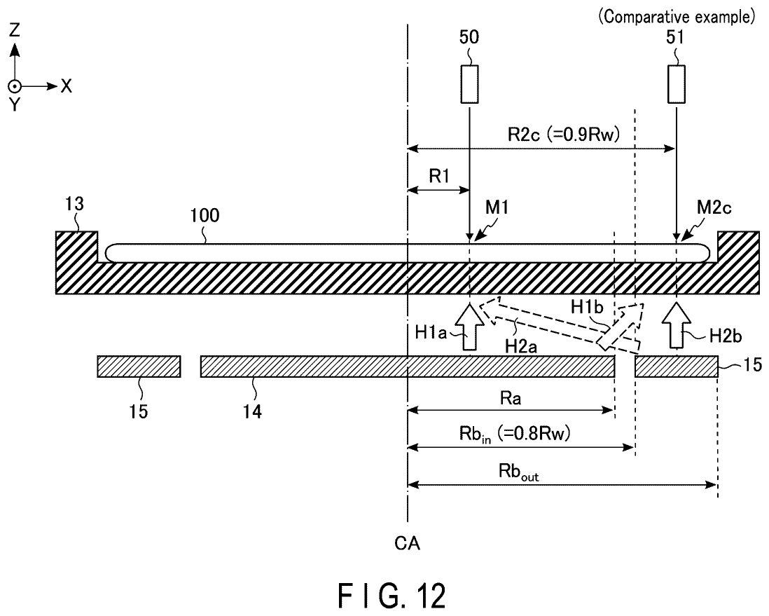

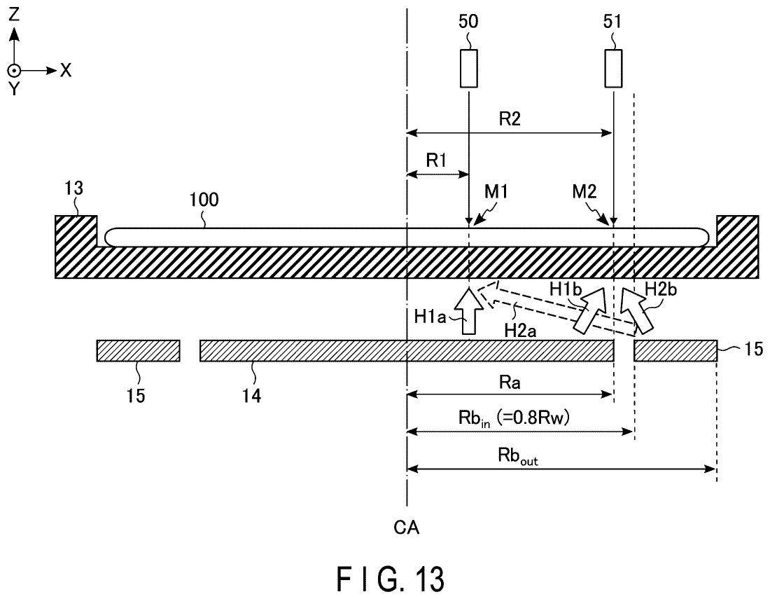

First, the relationship between the temperature measurement positions of the first and second radiation thermometers 50 and 51 and the first and second heaters 14 and 15 will be described with reference to FIGS. 12 and 13. FIG. 12 is a cross-sectional view of the susceptor 13, the first heater 14, the second heater 15, and the wafer 100 and illustrates the relationship, in a comparative example, between the temperature measurement positions of the first and second radiation thermometers 50 and 51 and the first and second heaters 14 and 15. FIG. 13 is a cross-sectional view of the susceptor 13, the first heater 14, the second heater 15, and the wafer 100 and illustrates the relationship, in an example of the present embodiment, between the temperature measurement positions of the first and second radiation thermometers 50 and 51 and the first and second heaters 14 and 15. In the description below, the focus will be placed on the positional relationship between the temperature measurement position M2 of the second radiation thermometer 51 and the second heater 15.

First, the positional relationship between the temperature measurement positions of the first and second radiation thermometers 50 and 51 and the first and second heaters 14 and 15 in the comparative example will be described.

As shown in FIG. 12, the temperature measurement position M1 of the first radiation thermometer 50 is provided above the first heater 14 in the comparative example. In the example shown in FIG. 12, the radius R1 of the temperature measurement position M1 is 0.2 times the radius Rw of the wafer 100 (R1=0.2 Rw), as in the cases shown in FIGS. 5 and 6. The radius Ra of the first heater 14 is, for example, 0.75 times the radius Rw of the wafer 100 (Ra=0.75 Rw). In a plan view seen from the Z direction, the radius R1 of the temperature measurement position M1 and the radius Ra of the first heater 14 satisfy the relationship 0≤R1<Ra. In other words, the distance R1 from the central axis CA to the temperature measurement position M1 is shorter than the distance (radius) Ra from the central axis CA to the outer periphery of the first heater 14.

In addition, the temperature measurement position M2c of the second radiation thermometer 51 is located above the second heater 15 in the comparative example. In the example shown in FIG. 12, the radius R2c of the temperature measurement position M2c is set at a position 0.9 times the radius Rw of the wafer 100 (R2c=0.9 Rw). For example, the inner radius Rbᵢₙ of the second heater 15 is set at a position 0.8 times the radius Rw of the wafer 100 (Rbᵢₙ=0.8 Rw). In a plan view seen from the Z direction, the radius R2c of the temperature measurement position M2c and the inner radius Rbᵢₙ and outer radius Rbₒᵤₜ of the second heater 15 satisfy the relationship Rbᵢₙ<R2c<Rbₒᵤₜ. In other words, the distance R2c from the central axis CA to the temperature measurement position M2c is longer than the distance (inner radius) Rbᵢₙ (=0.8Rw) from the central axis CA to the inner circumference of the second heater 15 and shorter than the distance (outer radius) Rbₒᵤₜ from the central axis CA to the outer circumference of the second heater 15. In this case, at the temperature measurement position M2c, the wafer 100 is mainly heated by the thermal radiation H2b from the second heater 15 via the susceptor 13, as in the comparative example of the first embodiment. The influence of the thermal radiation H1b from the first heater 14 on the temperature measurement position M2c is smaller than that of the thermal radiation H2b from the second heater 15.

Next, the positional relationship between the temperature measurement positions of the first radiation thermometer 50 and the second radiation thermometer 51 and the first and second heaters 14 and 15 in the example of the present embodiment will be described.

As shown in FIG. 13, the temperature measurement position M1 of the first radiation thermometer 50 of the example is provided above the first heater 14, as in the comparative example. In a plan view seen from the Z direction, the radius R1 of the temperature measurement position M1 and the radius Ra of the first heater 14 satisfy the relationship 0≤R1<Ra.

In the example, the temperature measurement position M2 of the second radiation thermometer 51 is located radially inward of the inner radius Rbin of the second heater 15, that is, it is positioned closer to the first heater 14. In a plan view seen from the Z direction, the radius R1 of the temperature measurement position M1, the radius R2 of the temperature measurement position M2, and the inner radius Rbᵢₙ of the second heater 15 satisfy the relationship R1<R2<Rbᵢₙ. In other words, the distance R2 from the central axis CA to the temperature measurement position M2 is longer than the distance (radius) Ra from the central axis CA to the outer periphery of the first heater 14 and shorter than the distance (inner radius) Rbᵢₙ from the central axis CA to the inner periphery of the second heater 15. In the example shown in FIG. 13, the inner radius Rbᵢₙ of the second heater 15 is provided at a position 0.8 times the radius Rw of the wafer 100 (Rbᵢₙ=0.8Rw), as in the case shown in FIG. 12. In this case, as in the first embodiment, the temperature measurement position M2 can be set to satisfy R1<R2<0.8 Rw. As in the example of the first embodiment, at the temperature measurement position M2, the wafer 100 (susceptor 13) is heated by the thermal radiation H1b from the first heater 14 and the thermal radiation H2b from the second heater 15. Therefore, the temperature of the second heater 15 for heating the temperature measurement position M2 is lower in the example than in the comparative example. That is, the apparent power supplied to the second heater 15 is lower in the example than in the comparative example. In a case where the apparent power supplied to the second heater 15 is reduced, the influence of the thermal radiation H2a from the second heater 15 on the temperature measurement position M1 becomes smaller. Therefore, the temperature of the first heater 14 for heating the temperature measurement position M1 is higher in the example than in the comparative example. That is, the apparent power supplied to the first heater 14 is higher in the example than in the comparative example. Therefore, in the case where the radius R2 of the temperature measurement position M2 is made smaller than the inner radius Rbᵢₙ of the second heater 15, the apparent power supplied to the first heater 14 tends to increase and the apparent power supplied to the second heater 15 tends to decrease.

### 2.2 Advantages of Present Embodiment

With the configuration according to the present embodiment, the temperature measurement position M2 of the second radiation thermometer 51 can be set to satisfy R1<R2<Rbᵢₙ. That is, the distance R2 from the central axis CA to the temperature measurement position M2 can be longer than the distance (radius) Ra from the central axis CA to the outer periphery of the first heater 14 and shorter than the distance (inner diameter) Rbᵢₙ from the central axis CA to the inner periphery of the second heater 15. This provides advantages similar to those of the first embodiment.

### 3. Third Embodiment

Next, a description will be given of the third embodiment. In connection with the third embodiment, a description will be given of a case where the setting range of the temperature measurement position M2 is determined based on the influence of the warpage of the wafer 100. In the description below, the focus will be placed on differences from the first and second embodiments.

### 3.1 Relationship Between Temperature Measurement Positions of First and Second Radiation Thermometers and Warpage of Wafer 100

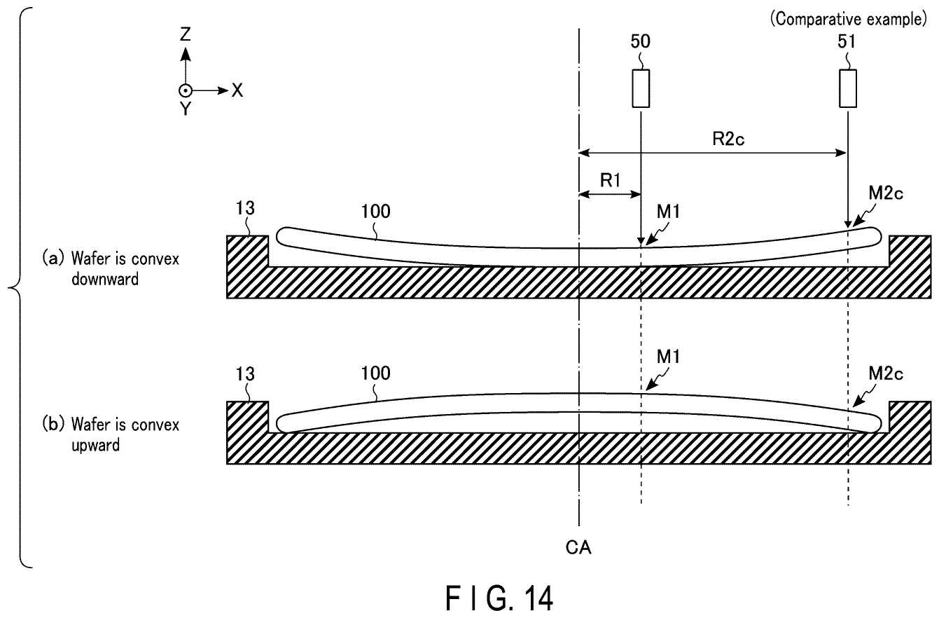

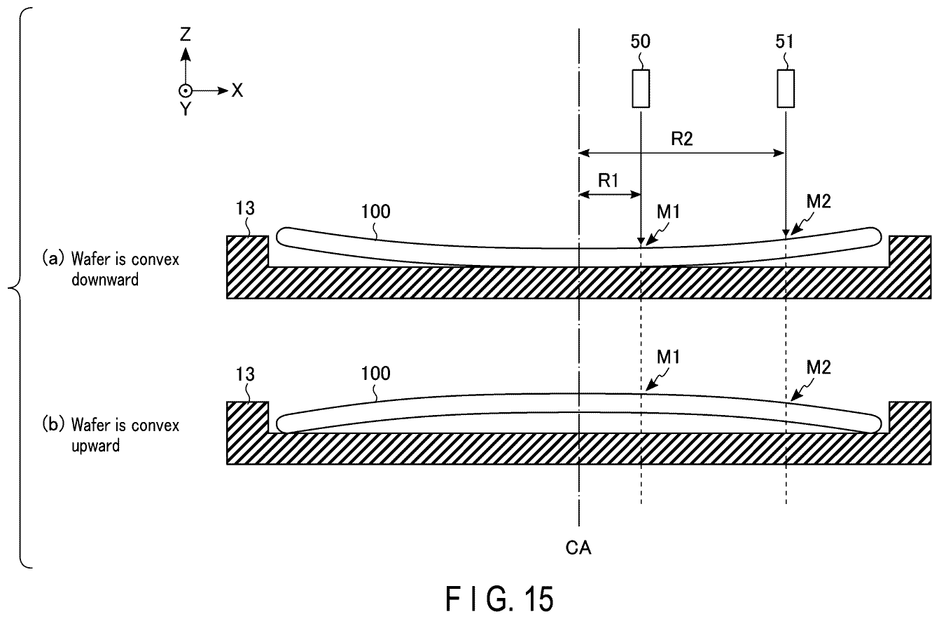

First, with reference to FIGS. 14 and 15, the relationship between the temperature measurement positions of the first and second radiation thermometers 50 and 51 and the warpage of the wafer 100 will be described. FIG. 14 is a cross-sectional view of the susceptor 13 and the wafer 100 and illustrates the relationship, in a comparative example, between the temperature measurement positions of the first and second radiation thermometers 50 and 51 and the warpage of the wafer 100. FIG. 15 is a cross-sectional view of the susceptor 13 and the wafer 100 and illustrates the relationship, in an example of the present embodiment, between the temperature measurement positions of the first and second radiation thermometers 50 and 51 and the warpage of the wafer 100. In the description below, the focus will be placed on the temperature measurement position M2 of the second radiation thermometer 51.

As shown in FIG. 14(a) and FIG. 15(a), the wafer 100 has a downward convex shape in the case where the residual stress of the wafer 100 is compressive stress.

As shown in FIG. 14(b) and FIG. 15(b), the wafer 100 has an upward convex shape in the case where the residual stress of the wafer 100 is tensile stress. The residual stress of the wafer 100, that is, the direction and amount of warpage of the wafer 100, varies from wafer to wafer.

As shown in FIG. 14(a) and FIG. 14(b), in the case of the comparative example, the difference between the distance between the wafer 100 and the susceptor 13 at the temperature measurement position M1 and the distance between the wafer 100 and the susceptor 13 at the temperature measurement position M2c is relatively large regardless of the residual stress (direction and amount of warpage) of the wafer 100. Thus, there is a difference in responsiveness between the temperature control of the first heater 14 based on the temperature measurement result at the temperature measurement position M1 and the temperature control of the second heater 15 based on the temperature measurement result at the temperature measurement position M2c. In addition, at the temperature measurement position M2c, the distance between the wafer 100 and the susceptor 13 varies relatively greatly depending on the direction of the warpage of the wafer 100. Therefore, the variation in temperature control (heater output) is relatively large from wafer to wafer. In other words, the reproducibility of temperature control between wafers is relatively low.

As shown in FIG. 15(a) and FIG. 15(b), in the example, the radius R1 of the temperature measurement position M1, the radius R2 of the temperature measurement position M2, and the radius Rw of the wafer 100 are set to satisfy the relationship 0≤R1<R2<0.8 Rw, as in the first embodiment. Thus, regardless of the residual stress (direction and amount of warpage) of the wafer 100, the difference between the distance between the wafer 100 and the susceptor 13 at the temperature measurement position M1 and the distance between the wafer 100 and the susceptor 13 at the temperature measurement position M2 can be reduced compared to the comparative example. Furthermore, at the temperature measurement position M2, the variation in the distance between the wafer 100 and the susceptor 13 caused by the direction of warpage of the wafer 100 can be reduced compared to the comparative example. Thus, the variation in temperature control (i.e., heater output) from wafer to wafer can be reduced compared to the comparative example. Therefore, variations in the temperature adjustment control of the first heater 14 and the second heater 15 caused by the residual stress of the wafer 100 can be suppressed. In other words, the reproducibility of temperature control between wafers can be made higher compared to the comparative example.

### 3.2 Advantages of Present Embodiment

With the configuration according to the present embodiment, the temperature measurement position M2 of the second radiation thermometer 51 can be set to satisfy R1<R2<0.8 Rw, as in the first embodiment. Thus, the variations in heater output between wafers caused by residual stress in the wafer 100 can be suppressed. Hence, the deterioration of the reproducibility of temperature control between wafers can be suppressed in the semiconductor manufacturing apparatus 1. Furthermore, the variations in the distances between the wafer 100 and the susceptor 13 at the temperature measurement positions M1 and M2 can be reduced by setting the temperature measurement position M2 of the second radiation thermometer 51 to satisfy R1<R2<0.8 Rw. Accordingly, the temperature variations in the wafer face can be reduced. Therefore, it is possible to suppress the occurrence of deformation, distortion, crystal defects, etc. of the wafer 100.

As the diameter of the wafer 100 increases, the amount of warpage tends to increase. Therefore, this advantage is effective for large-diameter wafers.

### 4. Others

While certain embodiments have been described, these embodiments have been presented by way of example only, and are not intended to limit the scope of the inventions. Indeed, the new embodiments described herein may be embodied in a variety of other forms. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus comprising:
a chamber;
a susceptor provided inside the chamber and capable of holding a wafer placed on an upper face thereof;
a rotating body provided inside the chamber and configured to rotate the susceptor about a predetermined central axis;
a first radiation thermometer provided above the chamber and configured to measure a temperature at a first temperature measurement position of the wafer placed on the susceptor;
a second radiation thermometer provided adjacent to the first radiation thermometer above the chamber and configured to measure a temperature at a second temperature measurement position of the wafer placed on the susceptor;
a first heater provided below the susceptor for heating a central region of the wafer;
a second heater provided below the susceptor for heating an outer region of the wafer; and
a controller that controls power applied to each of the first heater and the second heater to adjust the first temperature measurement position and the second temperature measurement position of the wafer to predetermined temperatures, based on temperature measurement data from the first radiation thermometer and the second radiation thermometer,
wherein a second distance from the central axis to the second temperature measurement position is longer than a first distance from the central axis to the first temperature measurement position and is shorter than 0.8 times a radius of the wafer.

2. The semiconductor manufacturing apparatus according to claim 1, wherein
in a case where the first distance is shorter than 0.5 times the radius of the wafer, the second distance is longer than 0.5 times the radius of the wafer and shorter than 0.8 times the radius of the wafer.

3. The semiconductor manufacturing apparatus according to claim 1, wherein
the first heater is provided below the susceptor and is controlled based on either a temperature measurement result obtained by the first radiation thermometer or a preset heater output, and
the second heater is provided below the susceptor so as to surround the first heater, has an annular shape, and is controlled based on either a temperature measurement result obtained by the second radiation thermometer or a preset heater output.

4. The semiconductor manufacturing apparatus according to claim 1, wherein the wafer has a center coinciding with the central axis.

5. The semiconductor manufacturing apparatus according to claim 1, further comprising a gas supply unit provided at an upper portion of the chamber,
wherein the gas supply unit includes:
a temperature measurement window provided on an upper face;
a rectifying plate configured to rectify gas flow; and
a plurality of nozzles passing through the rectifying plate, and
each of the first radiation thermometer and the second radiation thermometer receives thermal radiation emitted from a surface of the wafer through the temperature measurement window and one of the plurality of nozzles.

6. The semiconductor manufacturing apparatus according to claim 1, wherein
the first heater is provided below the susceptor and has a disk shape,
the second heater is provided below the susceptor so as to surround the first heater, has an annular shape, and has an inner diameter that is 0.8 times the radius of the wafer,
the first distance from the central axis to the first temperature measurement position is shorter than a radius of the first heater, and
the second distance from the central axis to the second temperature measurement position is longer than the first distance and shorter than the inner diameter of the second heater.
